(19) United States
(12) Patent Application Publication
(10) Pub. No.: US 2014/0213016 A1
(43) Pub. Date: Jul. 31, 2014

(54) IN SITU SILICON SURFACE PRE-CLEAN FOR HIGH PERFORMANCE PASSIVATION OF SILICON SOLAR CELLS

(71) Applicant: Applied Materials, Inc., Santa Clara, CA (US)

(72) Inventors: Shuran SHENG, Cupertino, CA (US); Lin ZHANG, San Jose, CA (US); Hari K. PONNEKANTI, San Jose, CA (US)

(73) Assignee: Applied Materials, Inc., Santa Clara, CA (US)

(21) Appl. No.: 14/160,171

(22) Filed: Jan. 21, 2014

Related U.S. Application Data
(60) Provisional application No. 61/758,542, filed on Jan. 30, 2013.

(51) Int. Cl. H01L 31/18

(52) U.S. Cl. CPC H01L 31/182; H01L 31/1804
USPC 438/97; 438/57

(57) ABSTRACT

Embodiments of the invention generally relate to methods for fabricating photovoltaic devices, and more particularly to methods for in-situ cleaning of a solar cell substrates. In one embodiment, a method of manufacturing a solar cell device is provided. The method comprises exposing a single or poly crystalline silicon substrate to a wet clean process to clean the surfaces of the crystalline substrate, loading the crystalline silicon substrate into a processing system having a vacuum environment, exposing at least one surface of the crystalline silicon substrate to an in-situ cleaning process in the vacuum environment of the processing system, and forming one or more passivation layers on at least one surface of the crystalline silicon substrate in the processing system.

### CROSS-REFERENCE TO RELATED APPLICATIONS

This application claims benefit of U.S. Provisional Patent Application Ser. No. 61/758,542, filed Jan. 30, 2013 which is herein incorporated by reference in its entirety.

### BACKGROUND

1. Field

Embodiments of the invention generally relate to methods for fabricating photovoltaic devices, and more particularly to methods for in-situ cleaning of a solar cell substrates.

2. Description of the Related Art

Solar cells are photovoltaic devices that convert sunlight directly into electrical power. The most common material utilized in a solar cell is silicon, which is generally in the form of single crystalline silicon, polycrystalline silicon, or amorphous silicon. The ratio of light converted into electrical power versus the amount of light shined on the front or light-receiving surface of the solar cell is a measurement of the efficiency of the solar cell. Improvements in fabricating techniques undertake the task of increasing the overall efficiency of a solar cell, while maintaining or reducing the cost to manufacture.

The efficiency of the solar cell may be enhanced by use of a passivation layer on the rear surface of a solar cell. When light passes from one medium to another, for example from air to glass, or from glass to silicon, some of the light may reflect off of the interface between the two media. The fraction of light reflected is a function of the difference in refractive index between the two media, wherein a greater difference in refractive indices of two adjacent media results in a higher fraction of light being reflected from the interface therebetween. Various layers disposed on the rear surface of the solar cell can reflect light back into the silicon where the reflected light can be absorbed, such as caused by the interface between two media, and increase the efficiency of a solar cell.

The efficiency at which a solar cell converts incident light energy into electrical energy is adversely affected by a number of factors. Such factors include the fraction of incident light reflected off the light receiving surface of a solar cell, the fraction of incident light not reflected off the rear surface of the solar cell, any other incident light not absorbed in the cell structure, and the recombination rate of electrons and holes within the solar cell. Each time an electron-hole pair recombines, a charge carrier is eliminated, thereby reducing the efficiency of the solar cell. Recombination may occur in the bulk silicon of a substrate, which is a function of the number of defects in the bulk silicon, or on the surface of a substrate, which is a function of how many non-terminated chemical bonds are on the substrate surface.

One function of a passivation layer is to minimize the carrier recombination at the rear surface a solar cell. One way to improve the passivation function of a passivation layer is to have a sufficient source of hydrogen available in the passivation layer for bulk and surface passivation. Another way to improve the passivation layer function is to provide a negative charge or a limited amount of net positive charge in the passivation layer to prevent the formation of a shunt current. Shunt current is an undesirable electrical short circuit between the front and back surface contacts of the solar cell. Thorough passivation of a solar cell by using a passivation layer greatly improves the efficiency of the solar cell by reducing recombination rates.

Current manufacturing processes of crystalline silicon solar cells typically include cleaning the crystalline silicon substrates from time to time prior to deposition of the passivation layer to remove oxidation and other impurities from solar cell substrates in an efficient way. The crystalline silicon substrates are typically cleaned using ex-situ wet processes before depositing surface passivation layers. However, after loading the crystalline silicon substrates into passivation layer deposition tools, surfaces of the crystalline silicon substrates may still be contaminated due to various reasons, for example, the presence of organic contaminants within processing chambers.

Therefore there is a need for efficient in-situ cleaning processes that will integrate well with efficient and high throughput production systems.

### SUMMARY

Embodiments of the invention generally relate to methods for fabricating photovoltaic devices, and more particularly to methods for in-situ cleaning of a solar cell substrates. In one embodiment, a method of manufacturing a solar cell device is provided. The method comprises exposing a single or poly crystalline silicon substrate to a wet clean process to clean the surfaces of the crystalline substrate, loading the crystalline silicon substrate into a processing system having a vacuum environment, exposing at least one surface of the crystalline silicon substrate to an in-situ cleaning process in the vacuum environment of the processing system, and forming one or more passivation layers on at least one surface of the crystalline silicon substrate in the processing system.

In another embodiment, a method of manufacturing a solar cell device is provided. The method comprises loading a crystalline silicon substrate into a processing system having a vacuum environment, exposing the crystalline silicon substrate to a hydrogen containing plasma in the vacuum environment of the processing system, and forming one or more passivation layers on at least one surface of the crystalline silicon substrate in the processing system.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIGS. 1A-1C are schematic cross-sectional views that illustrate a solar cell substrate during different stages of a solar cell processing sequence according to embodiments described herein;

FIG. 1D is a schematic cross-sectional view of a solar cell device formed according to embodiments described herein;

FIG. 2 is a block diagram illustrating a processing sequence performed on a substrate in a processing system according to embodiments described herein; and

FIG. 3 is a schematic isometric view of one embodiment of a processing system according to embodiments described herein.

It is to be noted, however, that the appended drawings illustrate only typical embodiments of this invention and are therefore not to be considered limiting of its scope, for the invention may admit to other equally effective embodiments.

### DETAILED DESCRIPTION

Embodiments of the invention generally relate to methods for fabricating photovoltaic devices, and more particularly to methods for in-situ cleaning of a solar cell substrates. The embodiments described herein may be used to effectively clean silicon-based solar substrates using reactive plasmas, sputter-based processes and/or non-plasma-based processes. In certain embodiments, soft H₂ or Ar containing plasmas may be used to clean the contaminated surface of crystalline silicon substrate. As demonstrated herein, the wafer surface recombination rate was significantly reduced with the measured minority carrier lifetime improved to >2 milliseconds from about 1 milliseconds by exposing a crystalline silicon (c-Si) solar substrate to a capacitively coupled (CCP) RF H₂ plasma (300 W, 30 sec) on an AKT 5500 PECVD tool available from Applied Materials, Inc.

Not to be bound by theory but it is believed that atomic H⁺ produced by H₂ plasma significantly reduces and even etches away native oxides, passivates surface defects, and even removes organic contaminants from the c-Si surfaces. Argon plasma cleaning is a sputtering process, with low selectivity to remove native and post-formed oxide, as well as organic contaminants and other impurities. Adding Ar to H₂ plasma (i.e. H₂/Ar plasma) can enhance the c-Si surface cleaning while still retaining good surface passivation.

In addition to H₂, Ar and H₂/Ar plasma chemistry for c-Si surface pre-clean, other hydrogen-containing gas, such as NH₃, CH₄, and oxygen-containing gases, such as O₂, O₃, N₂O, CO and CO₂ may also be used with the embodiments described herein. Inert gases, such as Ar, or He, may be supplied to stabilize the plasma. Halogen-containing gases, such as F₂, HF, NF₃, Cl₂, HCl, etc may be used for more aggressive cleaning and etching.

Suitable plasma sources used with the embodiments described herein may be based on DC, LF, RF, VHF or microwave discharges (CCP, inductively coupled plasma (ICP), remote, or magnetically enhanced). Plasma or ion sources may be in either point or linear configuration. Hot filaments may be used to generate high density of radicals (e.g. hydrogen radicals). Ultraviolet (UV) sources may also be used to generate high density radicals. Non-plasma-based cleaning processes include gas-phase (e.g. hot O₃, UV-excited Cl₂) cleaning, or mixed liquid (vapor)/gas jet spray cleaning processes (e.g. HF vapor/N₂, etc).

The plasma or ion sources used for the c-Si surface pre-clean can be implemented in a cluster-type, linear-type, or batch-type tools. The plasma sources may be implemented in process chambers, pre-heat chamber, buffer chambers, or dedicated pre-clean chambers. The atomic hydrogen or any other ions or radicals may be generated by a remote source and injected into the pass-through between chambers or into any appropriate chambers.

However, plasma damage of the c-Si surfaces has to be taken into account, as over-etching will damage the electronic properties of c-Si surfaces. Plasma damage may be repaired by annealing the substrate at temperatures at which the damaged c-Si surface region will be reconstructed or recrystallized, and defects may be suppressed and annealed. For example, plasma damage may be repaired at temperatures of around 550 to 800 degrees Celsius, or more precisely about 700 degrees Celsius during plasma or radical cleaning.

In certain embodiments, after the c-Si substrate is exposed to an ex-situ wet-clean process, the c-Si substrates are loaded into an entry loadlock and pumped down, the substrates are transferred to a pre-heat chamber and subject to a pre-clean of the c-Si substrate surfaces by a linear or point plasma/ion source. The plasma/ion source may generate H₂, Ar or H₂/Ar plasma. The c-Si substrates may be heated to suitable high temperatures by lamp radiation and/or resistive heaters for effective surface cleaning and damage recovery. After surface pre-clean, the c-Si substrates may be moved to the Al₂O₃ or SiNₓ process chamber for deposition of passivation layers.

In certain embodiments, the c-Si substrate surface pre-clean process is performed in the passivation layer deposition chambers (e.g., the Al₂O₃ or SiNx process chambers) with the dedicated sources installed for the pre-clean and deposition in the deposition chambers, respectively.

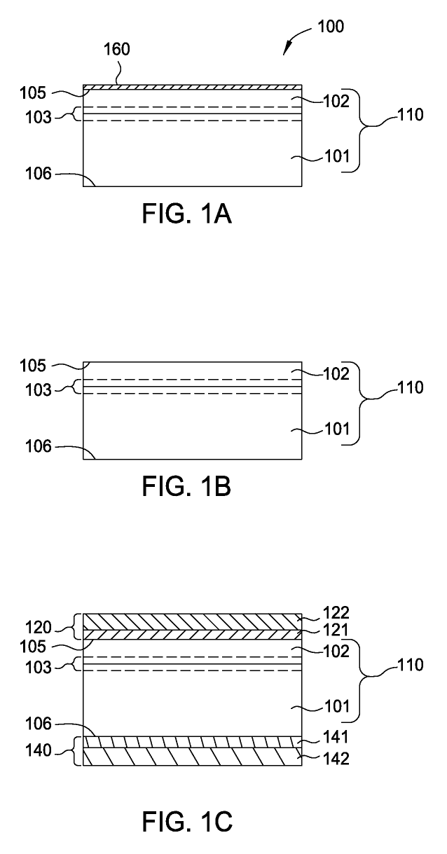

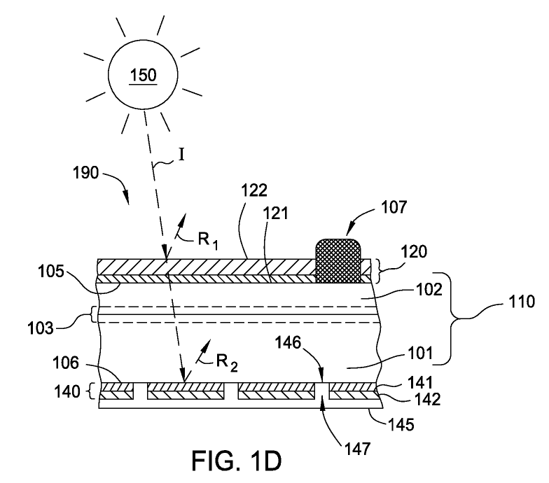

FIGS. 1A-1C are schematic cross-sectional views that illustrate a solar cell substrate 100 during different stages of a solar cell processing sequence according to embodiments described herein. FIG. 1D is a schematic cross-sectional view of a solar cell device 190 formed according to embodiments described herein. The process steps described herein may also be performed in a processing system described hereinafter according to certain embodiments described herein.

FIG. 1A illustrates a cross-sectional view of a solar cell substrate 110 having a layer of contaminants 160 formed thereon. The layer of contaminants 160 may comprise any of the following: native oxides, surface defects, organic contaminants and combinations thereof. The layer of contaminants 160 may be formed on the surface of the solar cell substrate 110 during transportation from one location to another. In certain embodiments, the layer of contaminants 160 may form when the solar cell substrate 110 is moved from an ex-situ location, such as a wet clean chamber, to a processing system for additional processing. In certain embodiments, the layer of contaminants may form on the surface of the solar cell substrate 110 when the solar cell substrate is moved in-situ within a processing system. For example, the processing chambers within the processing system may contain contaminants from previous processes performed in the processing chambers which form the layer of contaminants 160 on the surface of the solar cell substrate 110. In certain embodiments, this will occur after the solar cell substrate 110 enters the processing system and prior to the formation of a passivation layer on the surface of the solar cell substrate 110. It should be noted that while certain embodiments described herein are discussed in relation to cleaning a surface of a deposited layer, such as contaminant layer 160, this configuration is not intended to limit the scope of the invention, since the apparatus and cleaning processes described herein can be used during any phase of the solar formation process without deviating from the basic scope of the invention described herein. In certain embodiments, the processes described herein can be used to prepare the surfaces of the solar cell substrate 110, such as a crystalline silicon substrate, prior to depositing at least one of passivation stack 120 and passivation stack 140.

The solar cell substrate 110 has a front surface 105 on which the layer of contaminants 160 may be formed and a rear surface 106. Although not shown, it should be understood that a layer of contaminants 160 may also form on the rear surface. In one embodiment, the solar cell substrate 110 comprises a silicon substrate that has a p-type dopant disposed therein to form part of the solar cell device 190, which is further discussed below. In this configuration, the solar cell substrate 110 may have a p-type doped base region 101 and an n-doped emitter region 102 formed thereon, typically by a doping and diffusion/anneal process, although other processes including ion implant may be used. The substrate 110 also includes a p-n junction region 103 that is disposed between base region 101 and emitter region 102 of the solar cell, and the substrate 110 is the region in which electron-hole pairs are generated when solar cell device 190 is illuminated by incident photons “I” of light from the sun 150.

The solar cell substrate 110 may comprise single crystal silicon, multicrystalline silicon, or polycrystalline silicon, but may also be useful for substrates comprising germanium (Ge), gallium arsenide (GaAs), cadmium telluride (CdTe), cadmium sulfide (CdS), copper indium gallium selenide (CIGS), copper indium selenide (CuInSe₂), gallium indium phosphide (GaInP₂), organic materials, as well as heterojunction cells, such as GaInP/GaAs/Ge or ZnSe/GaAs/Ge substrates, that are used to convert sunlight to electrical power.

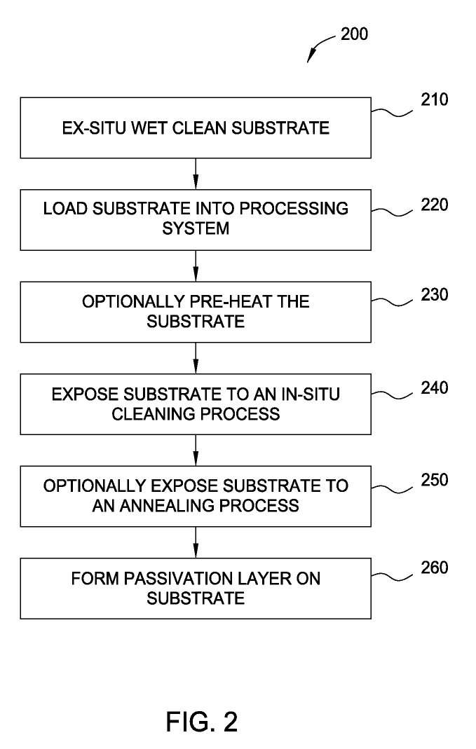

FIG. 1B illustrates a cross-sectional view of the solar cell substrate 110 after the layer of contaminants 160 has been remove according to embodiments described herein, for example, the method 200 described in FIG. 2.

FIG. 1C illustrates a cross-sectional view of the solar cell substrate 110 having a passivation/ARC layer stack 120 on the front surface (e.g., top surface 105) of the solar cell substrate 110 and a rear surface passivation layer stack 140 on the rear surface (e.g., rear surface 106) according to embodiments described herein. In one example, the passivation/ARC layer stack 120 and a rear surface passivation layer stack 140 each contain at least two or more layers of deposited material that are all formed on the substrate 110 in the processing system 300. The passivation/ARC layer stack 120 may comprise a first layer 121 that is in contact with the substrate surface 105 and a second layer 122 that is disposed on the first layer 121. In one example, the first layer 121 may comprise a silicon nitride (SiN) layer formed by a plasma enhanced chemical vapor deposition (PECVD) process that is between about 50 Angstroms (Å) and about 350 Å thick, such as 150 Å thick, and has a desirable quantity (Q₁) of trapped charge formed therein, to effectively passivate the substrate surface 105.

In one example, the second layer 122 may comprise a silicon nitride (SiN) layer formed by a PECVD process that is between about 400 Å and about 700 Å thick, such as 600 Å thick, which may have a desirable quantity (Q₂) of trapped charge formed therein, to effectively help bulk passivate the substrate surface 105. One will note that the type of charge, such as a positive or negative net charge based on the sum of Q₁ and Q₂, is preferentially set by the type of substrate over which the passivation layers are formed. However, in one example, a total net positive charge of between about 5×10¹¹ Coulombs/cm² to about 1×10¹³ Coulombs/cm² is desirably achieved over an n-type substrate surface, whereas a total net negative charge of between about 5×10¹¹ Coulombs/cm² to about 1×10¹³ Coulombs/cm² would desirably be achieved over a p-type substrate surface.

In this configuration, the rear surface passivation layer stack 140 may comprise a first backside layer 141 that is in contact with the substrate rear surface 106 and a second backside layer 142 that is disposed on the first backside layer 141. In one example, the first backside layer 141 may comprise an aluminum oxide (AlₓO_{y}) layer formed by a PECVD process that is between about 50 Angstroms (Å) and about 1300 Å thick, and has a desirable quantity (Q₃) of trapped charge formed therein, to effectively passivate the rear surface 106 of the solar cell substrate 110.

In one example, the second backside layer 142 may comprise a silicon nitride (SiN) layer formed by a PECVD process that is between about 600 Å and about 2,500 Å thick, which may have a desirable quantity (Q₄) of trapped charge formed therein, to effectively help passivate the rear surface 106 of the solar cell substrate 110. One will note that the type of charge, such as a positive or negative net charge based on the sum of Q₃ and Q₄, is preferentially set by the type of substrate over which the passivation layers are formed, as discussed above. In one embodiment of the solar cell device 190 the selection of the passivation/ARC layer stack 120 and a rear surface passivation layer stack 140 will minimize the front surface reflection R₁ and maximize the rear surface reflection R₂ in the formed device, respectively, as shown in FIG. 1C, to improve the efficiency of the solar cell device.

FIG. 1D illustrates a cross-sectional view of the formed solar cell device 190. The formed solar cell device 190 has front side electrical contacts 107 formed thereon and a conductive layer 145 that forms rear side electrical contacts 146 that electrically contact the surface of the substrate 110 through via regions 147 formed in the passivation layer stack 140. The conductive layer 145 and front side electrical contacts 107 may comprise a metal, such as the aluminum (Al), silver (Ag), tin (Sn), cobalt (Co), nickel (Ni), zinc (Zn), lead (Pb), tungsten (W), titanium (Ti), tantalum (Ta), nickel vanadium (NiV), or other similar materials, and combinations thereof.

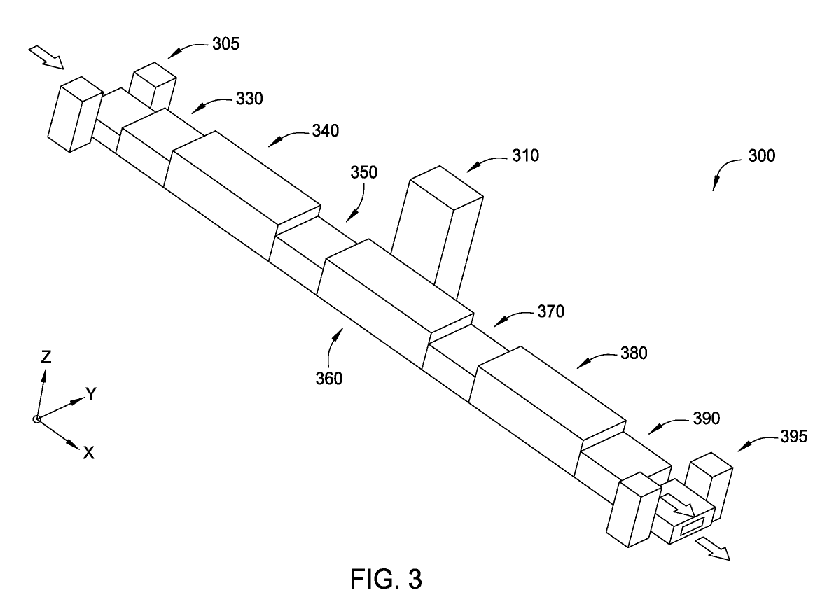

FIG. 2 is a block diagram illustrating a processing sequence 200 performed on a substrate in a processing system according to embodiments described herein. The process sequence may be used to remove the contaminant layer 160 from the solar cell substrate 110 as depicted in FIG. 1A and form the solar cell device 190 depicted in FIG. 1D. The process sequence 200 may be performed in any system having a source (e.g., plasma, radical, or ion) suitable for performing the pre-clean processes described herein. Exemplary system types on which the embodiments described herein may be performed include cluster-type, linear-type, or batch-type systems. One exemplary processing system 300 is depicted in FIG. 3.

At block 210, a substrate which may be similar to solar cell substrate 110 is exposed to a wet clean process. The cleaning processes performed on the substrate 110 prior to insertion into the processing system 300. The wet clean process is generally used to remove any undesirable materials that could affect the passivation layer properties and/or contaminate the processing regions of the processing system 300. The substrate 110 may be cleaned using a wet cleaning process in which a cleaning solution, such as a HF-last type cleaning solution, ozonated water cleaning solution, hydrofluoric acid (HF) and hydrogen peroxide (H₂O₂) solution, or other suitable cleaning solution. In some configurations, the substrates 110 may be a single crystal or multicrystalline silicon substrate, silicon containing substrate, doped silicon containing substrate, or other suitable substrates. In the embodiment depicted herein, the substrates 110 are p-type crystalline silicon (c-Si) substrates, as discussed above in conjunction with FIGS. 1A-1D.

At block 220, the substrate 110 is loaded into a processing system such as processing system 300. The substrate 110 may be loaded into a substrate receiving chamber such as substrate receiving chamber 305. The substrates 110 may be received from one or more modular substrate conveyors that are configured to receive cassettes or stack boxes containing multiple substrates. In one configuration, an actuator assembly (e.g., conveyor, robot) disposed in the substrate receiving chamber 305 is configured to transfer substrates from the modular substrate conveyors, which is at atmospheric pressure, into a dynamic load lock chamber so that they can then be moved through the processing chambers coupled to the processing region in the processing system 300.

At block 230, the substrates 110 may be exposed to a pre-heat process to prepare the substrate for cleaning or further processing. The substrates 110 are transferred through one or more chambers to prepare the substrates for the deposition processes performed in subsequent processing chambers. The pre-heat process may be performed in any chambers configured to adequately pre-heat the substrate 110. In certain embodiments, the pre-heat process may be performed in a pre-processing chamber, such as pre-processing chamber 330, prior to entering a deposition chamber. In certain embodiments, the pre-heat process may be performed in a deposition chamber, such as first processing chamber 340, second processing chamber 360 and third processing chamber 380. In certain embodiments, the pre-heat process may be performed in the pass-through or transfer chambers, such as transfer chambers 350 and 370.

In one configuration, the chambers configured to pre-heat the substrate 110 are configured to deliver energy, such as radiant heat to the substrates as they are transferred through the processing regions found in the chambers. In one example, the chamber components are configured to heat the substrates to a temperature between about 100 degrees Celsius and 450 degrees Celsius as they are transferred through the processing region of the of the pre-processing chamber. In some configurations, heating, cleaning, dry etching, doping or other similar processes may be performed on the plurality of substrates as they are serially transferred through the processing region of the chambers.

At block 240, the substrate is exposed to an in-situ cleaning process. The in-situ cleaning process may be performed to passivate surface defects and remove contaminants (e.g., native oxides and organic contaminants) from the surface of the substrate 110. The in-situ cleaning process may be a plasma-based process, a gas-phase process, or mixed liquid (vapor)/gas jet spray cleaning process.

The in-situ cleaning process is performed within a processing system, such as processing system 300. For example, the in-situ plasma cleaning process may be performed within any of the following: the pre-processing/pre-heat chamber, any of the processing/deposition chambers, and any of the pass-through/transfer chambers during the transfer of the substrate 110 through the processing system. In one embodiment, the in-situ cleaning process is performed in pre-processing chamber 330.

In certain embodiments, the in-situ cleaning process may be performed at a temperature range selected to prevent solar cell substrate 110 from heat damage, such as at a temperature less than about 800 degrees Celsius. Unlike conventional high temperature process, e.g., greater than 800 degrees Celsius, the low temperature in-situ plasma process can repair or remove contaminants from the surface of the substrate 110 without adversely impacting the film properties and existing device performance formed on the substrate 110. In one embodiment, the in-situ plasma process may be performed at a temperature less than about 800 degrees Celsius, such as between about 10 degrees Celsius and about 700 degrees Celsius, or between about 200 degrees Celsius and about 500 degrees Celsius.

In one embodiment, the in-situ cleaning process may be performed for a duration of about 10 seconds to about 300 seconds, for example, from about 30 seconds to about 240 seconds, and in one embodiment, from about 60 seconds to about 180 seconds. In certain embodiments where the in-situ cleaning process is a plasma-based process, the in-situ plasma process may be conducted at a plasma power, such as an inductive RF power at 13.56 MHz, setting from about 100 Watts to about 4,500 Watts, for example, from about 200 Watts to about 3,000 Watts, or about 300 Watts. The plasma process may be conducted with a duty cycle of about 2 percent to about 50 percent, or at 100 percent duty as continuous cycles and at a pulse frequency at about 10 kHz. In certain embodiments, the RF power is pulsed at a duty cycle of about 5 percent. In certain embodiments, the RF power is pulsed at about 5 percent duty cycle at a set point of about 800 Watts, resulting in an effective power of about 40 Watts effective plasma excitation power. Alternatively, the plasma power may be provided by other plasma sources, including a capacitively coupled plasma (CCP) source, an inductively coupled plasma (ICP) source, a remote plasma source, a magnetically enhanced plasma source, a hot-filament enhanced plasma source, a DC source, other suitable plasma, ion, or radical sources. Other non-plasma-based sources, such as hot filament (hydrogen) radical sources may be utilized for practicing the embodiments described herein.

The processing chamber may have a pressure from about 0 mTorr to about 5,000 mTorr. The optional inert gas may have a flow rate from about 20 standard cubic centimeters per minute (sccm) to about 200 standard liters per minute (slm), or from about 200 sccm to about 20,000 sccm, or from about 500 sccm to about 5,000 sccm.

In certain embodiments, the gas mixture used to perform the in-situ cleaning process may include at least one hydrogen containing gas, and optionally an inert gas, or other suitable gases. Examples of hydrogen containing gases include hydrogen (H₂), ammonia (NH₄), methane (CH₄), and combinations thereof. Examples of the inert gas include argon (Ar) or helium (He). In one exemplary embodiment described herein, the gas mixture comprises H₂ and Ar.

In certain embodiments, the gas mixture used to perform the in-situ cleaning process may include at least one inert gas. Examples of the inert gas include Ar or helium He. In one exemplary embodiment described herein, the gas mixture comprises Ar.

In certain embodiments, the in-situ based cleaning process is an oxygen-based process. The oxygen-based process may be a plasma process or a non-plasma process. The oxygen-based process may be used to burn/etch off organic contaminants from the substrate and/or chamber components and remove/drive out hydroxyl groups and hydrogen species from the surface of the substrate and/or chamber components. In certain embodiments, the gas mixture supplied to perform the in-situ cleaning process may include at least one oxygen containing gas, and optionally a nitrogen containing gas, an inert gas, or other suitable gas. Examples of the oxygen containing gas include O₂, N₂O, NO₂, NO, O₃, H₂O, and the like. Examples of the nitrogen containing gas include N₂, NH₃, N₂O, NO₂, NO and the like. Examples of the inert gas include Ar or He. In certain embodiments the gas mixture may include at least an oxygen containing gas. In another embodiment, the gas mixture may include at least a nitrogen containing gas and/or an oxygen containing gas. Alternatively, the inert gas may be supplied with the oxygen containing gas, nitrogen containing gas, or combination thereof in the gas mixture. In an exemplary embodiment depicted herein, the oxygen containing gas supplied in the gas mixture is N₂O, or O₂. In certain embodiments, the oxygen-containing plasma process or non-plasma based process is a gas-phase (heated O₃) cleaning or mixed liquid (vapor)/gas jet spray cleaning.

In certain embodiments, the gas mixture used to perform the in-situ cleaning process may include at least one halogen containing gas, and optionally an inert gas, or other suitable gases. Examples of the halogen containing gas may include F₂, HF, NF₃, Cl₂, HCl, and combinations thereof. Examples of the inert gas include Ar or He.

At block 250, the substrate is optionally exposed to an annealing process. The annealing process is typically performed within a processing system, such as processing system 300. For example, the annealing process may be performed within any of the following: the pre-processing/pre-heat chamber, any of the processing/deposition chambers, and any of the pass-through/transfer chambers during the transfer of the substrate 110 through the processing system. In one embodiment, the annealing process is performed in pre-processing chamber 330. The annealing process may be performed to repair any plasma damage from the in-situ plasma cleaning process. The annealing process may be performed at temperatures at which the damaged c-silicon surface region will be reconstructed or recrystallized, and defects may be suppressed and annealed. The annealing process may be performed at temperatures in the range of 550 to 800 degrees Celsius. In certain embodiments, the annealing process may be performed at about 700 degrees Celsius. Suitable annealing techniques include conventional furnace annealing, like a Rapid Thermal Annealing in H₂ or forming gas (H₂/N₂ mixture), either in vacuum or at atmospheric pressure; or rapid and selective electromagnetic (RF or MW) annealing methods which may enable lower thermal budget.

At block 260, a passivation layer is formed on the substrate 110. In certain embodiments, one or more passivation layer stack(s) 120 and 140 are formed on a solar cell substrate 110 having a light receiving surface 105 and a back surface 106 that is generally parallel and opposite to the light receiving surface on the substrate in a processing chamber. Generally, the substrate 110 is introduced into a processing chamber, such as a plasma enhanced chemical vapor deposition (PECVD) chambers, which are commercially available from Applied Materials, Inc. of Santa Clara, Calif. Any of deposition chambers 340, 360 and 380 may be configured as PECVD chambers. An example of a PECVD chamber design that may be adapted to perform one or more of the processes described herein is disclosed in the commonly assigned U.S. patent application Ser. No. 13/732,662, now published as U.S. 2013-0171757.

At block 260, one or more layers of a passivation/ARC layer stack 120 are formed on the front surface 105 of the solar cell substrate 110 using two or more deposition sources which are disposed in a portion of a processing region disposed in a processing chamber 340, as the substrates are transferred relative to the deposition sources by use of a substrate automation system. In one embodiment, the passivation/ARC layer stack 120 may comprise two or more antireflection/passivation layers, which may comprise silicon oxide and/or silicon nitride. In one example, during processing in the processing chamber a first gas source and a second gas source are configured to deliver one or more precursor gases or carrier gases to the surface of the substrates 110 by use of the deposition sources disposed in the processing chamber 340. The first gas source and the second gas source may be adapted to deliver silane (SiH₄), ammonia (NH₃), nitrogen (N₂), and hydrogen (H₂) to the processing region formed over the substrates 110. The power source may be adapted to deliver RF energy (e.g., 100 W to 4 kW at up to 13.56 MHz) to the process gasses disposed in the processing region over the substrates 110. In one embodiment, the first deposition source and second source are configured to form the first layer 121, of the passivation/ARC layer stack 120, by providing nitrogen (N₂) and silane (SiH₄) at a ratio (N₂/SiH₄) of about 1:1 or less while the substrates are maintained at a temperature of between about 300-450° C. by use of heating elements, RF power of about 2,000 to 10,000 Watts, for example 4,000 Watts, is provided by a power source and processing pressure of about 10 mTorr is maintained to form a silicon nitride (SiN) layer that is between about 50 Angstroms (Å) and about 350 Å thick on the surface of the substrate 110. A third deposition source and a fourth deposition source may also be configured to form a second layer 122 of the passivation/ARC layer stack 120 on the first layer 121, by providing nitrogen (N₂) and silane (SiH₄) at a ratio (N₂/SiH₄) of about 1:1 or greater and ammonia (NH₃) at a ratio to silane (NH₃/SiH₄) of about 1:1 while the substrates are maintained at a temperature of between about 300-450 degrees Celsius by use of the heating elements, RF power of about 2,000 to 10,000 Watts, for example 4,000 Watts, is provided by a power source and processing pressure of about 10 mTorr is maintained to form a silicon nitride (SiN) layer that is between about 400 Angstroms (Å) and about 700 Å thick on the surface of the substrate.

Optionally, the substrate 110 is reoriented so that a deposition process can be performed on the rear surface 106 of the substrate 110, which is on a side of the substrates 110 that are opposite to the front surface 105. In one configuration of the processing sequence 200, the substrates 110 are all reoriented in groups (e.g., at least one column of substrates (e.g., two substrates in a two row (R₁-R₂) configuration)). The substrates 110 may be reoriented in a transfer chamber, such as transfer chambers 350 and 370. In one example, to allow the substrates to be reoriented, the substrates disposed on the substrate automation system are transferred in groups into a reorienting device and then all of substrates disposed on the substrate automation system are momentarily stopped so that the reorienting device can “flip” the orientation of the substrates from a facing-up configuration to a facing-down configuration. One exemplary reorienting device is described in paragraphs [0082]-[0086] and depicted in FIGS. 7A-7B of commonly assigned U.S. patent application Ser. No. 13/732,662, filed Jan. 2, 2013, now published as US 2013-0171757.

In certain embodiments, after reorienting the substrate 110 it may be desirable to clean the second surface 106 of the substrate 110 prior to deposition of the rear surface passivation layer stack 140. The second surface 106 of the substrate 110 may be cleaned using the process describe in block 240.

A rear surface passivation layer stack 140 is deposited on the second surface 106 (e.g., back surface) of the substrate 110. The rear surface passivation layer stack 140 may be a dielectric layer providing good interface properties that reduce the recombination losses in the formed solar cell device. In one embodiment, the rear surface passivation layer stack 140 may be fabricated from a dielectric material selected from a group consisting of silicon nitride (Si₃N₄), silicon nitride hydride (SixNy:H), silicon oxide, silicon oxynitride, a composite film of silicon oxide and silicon nitride, an aluminum oxide layer, a tantalum oxide layer, a titanium oxide layer, or any other suitable materials. In one configuration, the rear surface passivation layer stack 140 comprises a first rear surface layer 141 that comprises aluminum oxide layer (Al₂O₃). The aluminum oxide layer (Al₂O₃) may be formed by using two or more deposition sources, which are disposed in the portion of the processing region disposed in a processing chamber, such as processing chamber 360 as the substrates are transferred relative to the deposition sources by use of a substrate automation system. In one example, during processing in the processing chamber a first gas source and a second gas source are configured to deliver one or more precursor gases or carrier gases to the surface of the substrates 110 by use of the deposition sources disposed in the processing chamber 360. The first gas source and the second gas source may be adapted to deliver trimethylaluminum (TMA) and oxygen (O₂) to the processing region formed over the substrates 110. The power source may be adapted to deliver RF energy (e.g., 100 W to 10 kW at up to 13.56 MHz) to the process gasses disposed in the processing region over the substrates 110. In one embodiment of the process sequence 200, the first deposition source and second source are configured to form the first rear surface layer 141 by providing trimethylaluminum (TMA) and oxygen (O₂) at a ratio (TMA/O₂) of about 1:3 while the substrates are maintained at a temperature of about 350° C. by use of the heating elements, RF power of about 4,000 Watts is provided by a power source and processing pressure of about 10 mTorr is maintained to form a aluminum oxide layer (Al₂O₃) layer that is between about 50 Angstroms (Å) and about 1,200 Å thick on the surface of the substrates 110.

Optionally the second rear surface layer 142 in the rear surface passivation layer stack 140 is deposited on the first rear surface layer 141 disposed on the second surface 106 (e.g., back surface) of the substrates 110. The second rear surface layer 142 may be a dielectric layer that provides good insulating properties, bulk passivation properties and act as a diffusion barrier for the subsequent metallization layers. The second rear surface layer 142 may be formed on the second surface 106 of the substrates 110 using two or more deposition sources, which are disposed in the portion of the processing region disposed in a processing chamber such as processing chamber 380, as the substrates are transferred relative to the deposition sources. In one example, the second rear surface layer 142 may comprise one or more passivation layers, which may comprise silicon nitride. In one example, during processing in the processing chamber a first gas source and a second gas source are configured to deliver one or more precursor gases or carrier gases to the surface of the substrates 110 by use of the deposition sources disposed in the processing chamber. The first gas source and the second gas source may be adapted to deliver silane (SiH₄), ammonia (NH₃), nitrogen (N₂), and hydrogen (H₂) to the processing region formed over the substrates 110. The power source may be adapted to deliver RF energy (e.g., 100 W to 10 kW at up to 13.56 MHz) to the process gasses disposed in the processing region over the substrates 110. In one embodiment, the first deposition source, second source, third source and fourth source in the processing chamber are configured to form the second rear surface layer 142 on the first rear surface layer 141, by providing nitrogen (N₂) and silane (SiH₄) at a ratio (N₂/SiH₄) of about 1:1 or greater and ammonia (NH₃) at a ratio to silane (NH₃/SiH₄) of about 1:1 while the substrates are maintained at a temperature of between about 300-450 degrees Celsius by use of heating elements, RF power of about 4000 Watts is provided by a power source and processing pressure of about 10 mTorr is maintained to form a silicon nitride (SiN) layer that is between about 400 Angstroms (Å) and about 700 Å thick on the surface of the substrate.

The substrate 110 may be further processed in a processing chamber, such as processing chamber 390, prior to exiting the processing system 300. These post processing steps may be performed in one or more additional processing chambers as necessary to help reliably form a desirable solar cell device. In one embodiment, the post processing steps may include thermal processing (e.g., rapid thermal annealing, dopant drive-in steps) steps, laser ablation of regions of the substrates 110 to open vias in the passivation layers formed on either surface of the substrate to subsequently form back-surface-field (BSF) regions and electrical contacts to the surfaces of the substrates 110, and/or other deposition process steps, such as PVD or evaporation type contact layer deposition steps. In one example, an aluminum containing layer is deposited over the rear surface passivation layer stack 140 in the processing chamber 390 by an evaporation process to form metal contacts to portions of the rear surface 106 of the substrates 110. The contact regions created on the substrates 110 may have been formed by use of a laser ablation process that was performed after the rear surface passivation layer stack 140 was formed and before the aluminum layer deposition process steps.

FIG. 3 is a schematic isometric view of one embodiment of a processing system 300 according to embodiments described herein. Embodiments of the present invention generally provide a high throughput substrate processing system 300, or cluster tool, for in-situ cleaning and processing of a film stack used to form regions of a solar cell device. In one configuration, solar cell substrates are cleaned in-situ in the processing system 300 and one or more film stacks are formed on each of the substrates. The film stacks may contain one or more passivating or dielectric layers that are deposited and further processed within one or more processing chambers contained within the high throughput substrate processing system 300. The processing chambers may be, for example, plasma enhanced chemical vapor deposition (PECVD) chambers, low pressure chemical vapor deposition (LPCVD) chambers, atomic layer deposition (ALD) chambers, physical vapor deposition (PVD) chambers, thermal processing chambers (e.g., RTA or RTO chambers), pre-heat chamber, pre-clean chambers, substrate reorientation chambers (e.g., flipping chambers) and/or other similar processing chambers.

The high throughput substrate processing system 300 may include one or more deposition chambers in which substrates are exposed to one or more gas-phase materials and an RF plasma. In one embodiment, the processing system 300 includes at least one plasma enhanced chemical vapor deposition (PECVD) processing chamber that has been adapted to simultaneously process a plurality of substrates as they pass through the system 300 in a linear direction. In one embodiment, solar cell substrates are simultaneously transferred in a vacuum or inert environment through the linear system 300 to prevent substrate contamination and improve substrate throughput. In certain embodiments, the substrates are arranged in a linear array for processing as opposed to processing vertical stacks of substrates (e.g., batches of substrates stacked in cassettes) or planar arrays of substrates that are typically transferred on a substrate carrier in a batch. Such processing of substrates arranged in linear arrays allows each of the substrates to be directly and uniformly exposed to the generated plasma, radiant heat, and/or processing gases. The linear array may contain sub-sets or groups of the substrates that are similarly processed as they are serially transferred through the processing system. In this configuration, the sub-sets or groups of substrates are generally substrates disposed in the linear array that are similarly aligned in a direction perpendicular to the substrate transfer direction, and thus will be similarly processed at any given time during the processing sequence. Thus, processing groups of substrates that are disposed in linear arrays does not rely on diffusion type processes or the serial transfer of energy from one substrate to the next, such as undesirably found in conventionally configured vertical stack or back-to-back batch substrate processing.

Embodiments of the invention disclosed herein can be used to rapidly form the next generation solar cell devices in a high throughput substrate processing system 300. In some configurations, the next generation solar cell devices will contain multiple deposited layers, such as advanced passivation layers (i.e. passivation layer stacks 120 and 140), that are formed on both sides of a solar cell substrate in the processing system 300. Forming layers, such as high quality passivation layers with reduced contaminants, on both sides of the substrate can reduce carrier recombination, redirect electrons and holes back into the solar cells to generate a desirable photocurrent, and act as a rear side reflector to better collect the incident solar energy. However, as one skilled in the art will appreciate, the ability of a processing system to form and process multiple high quality layers on both sides of a substrate, while maintaining a high substrate throughput (e.g., >3,000 substrates per hour) and provide a repeatable and desirable film quality has been elusive for the solar cell fabrication industry. The processing system configurations described herein are thus generally configured to reliably form a high quality advanced passivation layer on both surfaces of a solar cell substrate.

In one embodiment, the substrate processing system 300 may include a substrate receiving chamber 305, pre-processing chamber 330, at least one processing chamber maintained at a pressure below that of atmospheric pressure, such as a first processing chamber 340, a second processing chamber 360, and a third processing chamber 380, at least one transferring chamber, such as transferring chambers 350 and 370, a buffer chamber 390 and a substrate unload chamber 395. Collectively, the processing chambers 330-390 may include one of the following types of chambers: pre-clean chamber, pre-heat chambers, PECVD chambers, LPCVD chambers, hot wire filament chambers, hot wire chemical vapor deposition (HWCVD) chambers, ion implant/doping chambers, plasma nitridation chambers, atomic layer deposition (ALD) chambers, physical vapor deposition (PVD) or sputtering chambers, plasma or vapor chemical etching chambers, thermal processing chambers (e.g., RTA or RTO chambers), substrate reorientation chambers (e.g., flipping chambers) and/or other similar processing chambers. Further description of an advanced platform for passivating crystalline silicon solar cells that may be used by embodiments herein is disclosed in commonly assigned U.S. patent application Ser. No. 13/732,662, filed on Jan. 2, 2013.

In certain embodiments, the process may proceed by exposing the substrate to an in-situ pre-clean process in the pre-processing chamber 330 and processing the substrates in a first processing chamber 340 and a second processing chamber 360, flipping the substrates in a substrate reorientation chamber, and further processing the substrate in a third processing chamber similar to the first processing chamber, and a fourth processing chamber similar to the second processing chamber. In this embodiment, passivation layer stacks may be formed on both the light receiving surface of the substrates and the back surface of the substrates. It is contemplated that other processing sequences may be performed to achieve the desired passivation layer stack deposition and the aforementioned embodiment should not be construed as limiting the invention.

Generally, the processing system 300 includes a system controller 310 configured to control the automated aspects of the system. The system controller 310 facilitates the control and automation of the overall substrate processing system 300 and may include a central processing unit (CPU) (not shown), memory (not shown), and support circuits (or I/O) (not shown). The CPU may be one of any form of computer processors that are used in industrial settings for controlling various chamber processes and hardware (e.g., conveyors, motors, fluid delivery hardware, etc.) and monitor the system and chamber processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 310 determines which tasks are performable on a substrate. Preferably, the program is software readable by the system controller 310, which includes code to generate and store at least substrate positional information, the sequence of movement of the various controlled components, and any combination thereof.

### EXAMPLES

The following non-limiting examples are provided to further illustrate embodiments described herein. However, examples are not intended to be all inclusive and are not intended to limit the scope of the embodiments described herein.

Samples #1-3 were performed on p-type CZ silicon bare wafers in an AKT-5500 PECVD chamber available from Applied Materials. The bare wafers were exposed to a hot-pass process to expose the wafers to possible residual contaminants present in the PECVD chamber. The hot-pass process may be performed with or without lamp heating. Exemplary hot-pass processes include: pre-processing chambers PH2, 330: 20% lamp power, heaters at 650° C.; AlO processing chamber, 340: heaters at 650° C.; transfer chamber PH3, 350: 20% lamp power, heaters at room temperature; SiN processing chamber, 360: heaters at 700° C. The hot-pass process was performed without deposition and without exposure to plasma to monitor the chamber environment. After exposure to the hot-pass process the minority carrier lifetime was measured and is disclosed in the column labeled “Hot Pass as measured”. After the hot-pass process, Sample #1 was exposed to hydrogen plasma (300 W) for a period of 30 seconds; Sample #2 was exposed to hydrogen plasma (900 W) for a period of 30 seconds; and Sample #3 was exposed to argon plasma (900 W) for a period of 30 seconds. As shown in Table I, both the minority carrier lifetimes of Sample #1 and Sample #3 improved after plasma treatment. However, Sample #2 demonstrated a decrease in the minority carrier lifetime. It is believed that the power during hydrogen plasma of Sample #2 was too high leading to damage of the silicon surface.

TABLE 1

| | | H2 pls, | H2 pls, | Ar pls, (900 W, |
|---|---|---|---|---|
| | Hot Pass as | (300 W, 30 | (900 W, 30 | 30 |
| | measured | seconds) | seconds) | seconds) |
| Sample #1 | 1,156 μs | 2,379 μs | | |
| Sample #2 | 1,156 μs | | 300 μs | |
| Sample #3 | 500 μs | | | 581 μs |

As demonstrated in Table I, the wafer surface recombination rate was significantly reduced with the measured minority carrier lifetime improved to >2 milliseconds from about 1 milliseconds by exposing a crystalline silicon (c-Si) solar substrate to a capacitively coupled (CCP) RF H₂ plasma (300 W, 30 sec) on an AKT 5500 PECVD tool available from Applied Materials, Inc.

While the foregoing is directed to embodiments of the present invention, other and further embodiments of the invention may be devised without departing from the basic scope thereof, and the scope thereof is determined by the claims that follow.

1. A method of manufacturing a solar cell device, comprising:
exposing a single or poly crystalline silicon substrate to a wet clean process to clean the surfaces of the crystalline silicon substrate;
loading the crystalline silicon substrate into a processing system having a vacuum environment;
exposing at least one surface of the crystalline silicon substrate to an in-situ cleaning process in the vacuum environment of the processing system; and
forming one or more passivation layers on the at least one surface of the crystalline silicon substrate in the vacuum environment of the processing system.

2. The method of claim 1, wherein the in-situ cleaning process comprises exposing the crystalline silicon substrate to a hydrogen-containing plasma.

3. The method of claim 2, wherein the hydrogen-containing plasma further comprises an inert gas selected from the group consisting of: argon, helium, and combinations thereof.

4. The method of claim 2, wherein the hydrogen-containing plasma comprises a hydrogen-containing gas selected from the group consisting of: hydrogen, ammonia, methane, and combinations thereof.

5. The method of claim 1, wherein the in-situ cleaning process comprises exposing the crystalline silicon substrate to an oxygen-containing gas selected from the group consisting of: O₂, O₃, N₂O, CO₂, CO and combinations thereof.

6. The method of claim 1, wherein the in-situ cleaning process comprises exposing the crystalline silicon substrate to a halogen-containing plasma comprising a halogen-containing gas selected from the group consisting of: F₂, HF, NF₃, Cl₂, HCl, and combinations thereof.

7. The method of claim 1, wherein the in-situ cleaning process comprises exposing the crystalline silicon substrate to an argon containing plasma.

8. The method of claim 1, further comprising annealing the crystalline silicon substrate after exposing at least one surface of the crystalline silicon substrate to an in-situ cleaning process in the vacuum environment of the processing system and before forming one or more passivation layers on the at least one surface of the crystalline silicon substrate in the vacuum environment of the processing system.

9. The method of claim 8, wherein annealing the crystalline silicon substrate is performed at temperatures in the range of 500 to 800 degrees Celsius.

10. The method of claim 1, wherein the in-situ cleaning process is performed under vacuum in the processing system in at least one of: a processing chamber, a pre-heating chamber, a buffer chamber, a pass-through in between chambers and a dedicated pre-clean chamber.

11. The method of claim 1, wherein the in-situ cleaning process is a plasma-based process.

12. The method of claim 11, wherein the plasma is formed from a plasma source selected from a capacitively coupled plasma source, an inductively coupled plasma source, a remote plasma source, a magnetically enhanced plasma source, a hot-filament enhanced plasma source, a DC source and an RF source.

13. The method of claim 1, further comprising exposing the crystalline silicon substrate to an ex-situ wet-clean process prior to loading the crystalline silicon substrate into a processing system having a vacuum environment.

14. The method of claim 1, further comprising pre-heating the substrate to a temperature between about 100 degrees Celsius and 450 degrees Celsius after loading the crystalline silicon substrate into a processing system having a vacuum environment and prior to exposing at least one surface of the crystalline silicon substrate to an in-situ cleaning process in the vacuum environment of the processing system.

15. The method of claim 1, wherein the in-situ plasma process is performed at a temperature between about 200 degrees Celsius and about 500 degrees Celsius.

16. A method of manufacturing a solar cell device, comprising:
loading a crystalline silicon substrate into a processing system having a vacuum environment;
exposing at least one surface of the crystalline silicon substrate to a hydrogen containing plasma in the vacuum environment of the processing system; and
forming one or more passivation layers on the at least one surface of the crystalline silicon substrate in the vacuum environment of the processing system.

17. The method of claim 16, wherein the hydrogen-containing plasma further comprises an inert gas selected from the group consisting of: argon, helium, and combinations thereof.

18. The method of claim 17, wherein the hydrogen-containing plasma is a capacitively coupled plasma.

19. The method of claim 16, further comprising annealing the crystalline silicon substrate after exposing the crystalline silicon substrate to a hydrogen containing plasma in the vacuum environment of the processing system and before forming one or more passivation layers on at least one surface of the crystalline silicon substrate in the vacuum environment of the processing system.

20. The method of claim 16, wherein the exposing the crystalline silicon substrate to a hydrogen containing plasma in the vacuum environment of the processing system is performed under vacuum in the processing system in at least one of: a processing chamber, a pre-heating chamber, a buffer chamber, a pass-through in between chambers or a dedicated pre-clean chamber.
